(19) United States
(12) Patent Application Publication
(10) Pub. No.: US 2014/0349219 A1
(43) Pub. Date: Nov. 27, 2014

(54) EXPOSURE METHOD, REFLECTION TYPE MASK, AND SEMICONDUCTOR DEVICE MANUFACTURING METHOD

(71) Applicant: Kabushiki Kaisha Toshiba, Minato-ku (JP)

(72) Inventors: Hiroyuki MIZUNO, Kuwana-shi (JP); Yosuke Okamoto, Hachioji-shi (JP); Takeshi Koshiba, Yokkaichi-shi (JP); Satoshi Nagai, Yokkaichi-shi (JP)

(73) Assignee: Kabushiki Kaisha Toshiba, Minato-ku (JP)

(21) Appl. No.: 14/088,743

(22) Filed: Nov. 25, 2013

(30) Foreign Application Priority Data
May 23, 2013 (JP) 2013-109151

(51) Int. Cl. G03F 7/20; G03F 1/24

(52) U.S. Cl. CPC G03F 7/20; G03F 1/24
USPC 430/5; 430/322; 430/319

(57) ABSTRACT

According to embodiments, an exposure method is provided. In the exposure method, a transmittance of a pellicle is adjusted every position of a mask pattern included in a reflection type mask. And when adjusting the transmittance of the pellicle, a film thickness of the pellicle is adjusted on the basis of a transmittance correction amount. Thereafter, exposure is conducted onto a substrate by using the reflection type mask with the pellicle stuck thereon.

### CROSS-REFERENCE TO RELATED APPLICATIONS

This application is based upon and claims the benefit of priority from Japanese Patent Application No. 2013-109151, filed on May 23, 2013; the entire contents of which are incorporated herein by reference.

### FIELD

Embodiments of the present invention relate to an exposure method, a reflection type mask, and a semiconductor device manufacturing method.

### BACKGROUND

In exposure apparatuses such as ArF immersion exposure apparatuses, a dose mapper, a CDC or the like is used to improve the dimension precision of patterns formed on wafers. The dose mapper changes an amount of light with which an exposure apparatus irradiates a mask, in an arbitrary position on the mask. An amount of this change in the amount of light is represented as a polynomial of coordinates in a shot. However, the exposure apparatus cannot cope with correction of high-order components.

Furthermore, the CDC functions to scatter a part of exposure light that passes through a transmission type mask by providing small scratches in the transmission type mask and thereby control the amount of light that reaches a wafer face. Since in the CDC the density with which scratches are provided is controlled by using a high order function or spline approximation in order to control the amount of exposure, high precision correction is possible. Since the transmission type mask itself is provided with scratches, it becomes an irreversible correction to the transmission type mask.

In EUV exposure apparatuses using a reflection type mask, correction of the dimensions in the shot using the dose mapper is possible only for low order components in the same way as the ArF immersion exposure apparatuses. In the EUV exposure apparatuses, however, an EUV mask is reflection type and consequently it is difficult to apply the CDC and correction of high order components cannot be conducted. In the reflection type exposure apparatuses such as the EUV exposure apparatuses as well, therefore, it is desired to conduct high precision correction of patterns formed on the wafer.

### BRIEF DESCRIPTION OF THE DRAWINGS

FIG. 1 is a diagram illustrating a sectional configuration of a mask according to a first embodiment;

FIG. 2 is a flow chart illustrating a processing procedure of an exposure method according to the first embodiment;

FIG. 3A is a diagram illustrating a relation between a dimension deviation amount of a mask pattern and a dimension deviation amount of a wafer pattern;

FIG. 3B is a diagram illustrating a relation between an exposure amount and a wafer pattern dimension;

FIG. 3C is a diagram illustrating a relation between the exposure amount and a transmittance;

FIG. 3D is a diagram illustrating a relation between a pellicle etching amount and a transmittance correction amount;

FIG. 4A is a diagram illustrating an example of a mask dimension deviation amount map;

FIG. 4B is a diagram illustrating an example of a transmittance correction map;

FIG. 4C is a diagram illustrating an example of a pellicle etching amount map;

FIG. 5 is a flow chart illustrating a processing procedure of an exposure method according to a second embodiment;

FIG. 6 is a diagram for explaining a relation between an irradiation angle of exposure light and a position where the exposure light passes through a pellicle; and

FIG. 7 is a diagram illustrating a sectional configuration of a mask according to a fourth embodiment.

### DETAILED DESCRIPTION

According to embodiments, an exposure method is provided. In the exposure method, a transmittance of a pellicle is adjusted every position of a mask pattern included in a reflection type mask. And when adjusting the transmittance of the pellicle, a film thickness of the pellicle is adjusted on the basis of a transmittance correction amount. Thereafter, exposure is conducted onto a substrate by using the reflection type mask with the pellicle stuck thereon.

Hereafter, an exposure method, a reflection type mask, and a semiconductor device manufacturing method according to embodiments will be described in detail with reference to the accompanying drawings. By the way, the present invention is not restricted by these embodiments.

### First Embodiment

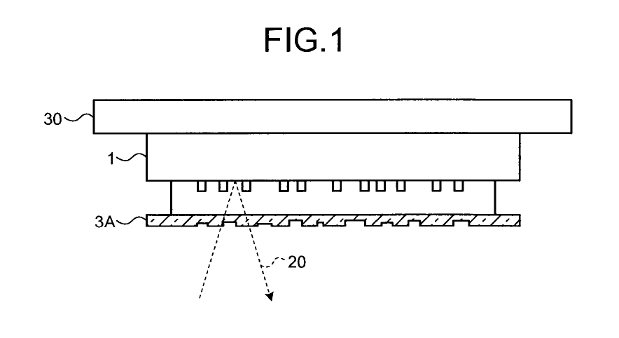

FIG. 1 is a diagram illustrating a sectional configuration of a mask according to a first embodiment. In the present embodiment, a case where a mask on which a pellicle 3A is stuck is a product mask 1 will be described. The product mask 1 is a reflection type mask such as an EUV (Extreme Ultraviolet) mask, and it is applied to a reflection type exposure apparatus such as an EUV exposure apparatus.

The pellicle 3A in the present embodiment is controlled in transmittance. As a result, the amount of exposure light with which the top of a mask pattern is irradiated is adjusted (adjustment worked) to an arbitrary magnitude. As a result, a wafer pattern dimension in a shot is made to have a desired value. In other words, the product mask 1 is a mask that is adjusted in transmittance by the pellicle 3A to correct the wafer pattern dimension.

The product mask 1 is held from its back side by a mask holding unit 30 included in the exposure apparatus. In a state in which the product mask 1 is held by the mask holding unit 30, the product mask 1 is irradiated with exposure light (such as EUV light) 20 from its surface side.

The mask pattern is formed on the surface side of the product mask 1. The product mask 1 in the present embodiment has the pellicle 3A. The pellicle 3A is stuck on the surface side of the product mask 1 in a position located at a predetermined distance from the mask pattern. The pellicle 3A transmits the exposure light 20 and prevents foreign matters such as particles from adhering to the mask pattern.

As for the pellicle 3A in the present embodiment, various thicknesses are set every area. Since the pellicle 3A has a transmittance according to the thickness, a wafer pattern according to a film thickness (transmittance) of the pellicle 3A is formed on a wafer. In the pellicle 3A, the thickness is adjusted every area to form a wafer pattern having a predetermined dimension.

For example, a case where a first position of the pellicle 3A is located in an area right over a second position of the mask pattern and the mask pattern in the second position is transferred to a third position of the wafer pattern will now be considered. If in this case a dimension of the wafer pattern in the third position is thicker than a desired value, transmittance in the first position is lowered by making the film thickness of the pellicle 3A in the first position thin.

If the surface of the product mask 1 is irradiated with the exposure light 20, the exposure light 20 passes through the pellicle 3A and arrives at the mask pattern. In the exposure light 20, the exposure light 20 with which a position on the mask pattern is irradiated is absorbed by the mask pattern, whereas the exposure light 20 with which a position other than the mask pattern is irradiated is reflected by the product mask 1. The exposure light 20 reflected by the product mask 1 passes through the pellicle 3A and the top of a semiconductor substrate such as a wafer (not illustrated) is irradiated with exposure light 20 that passes through the pellicle 3A.

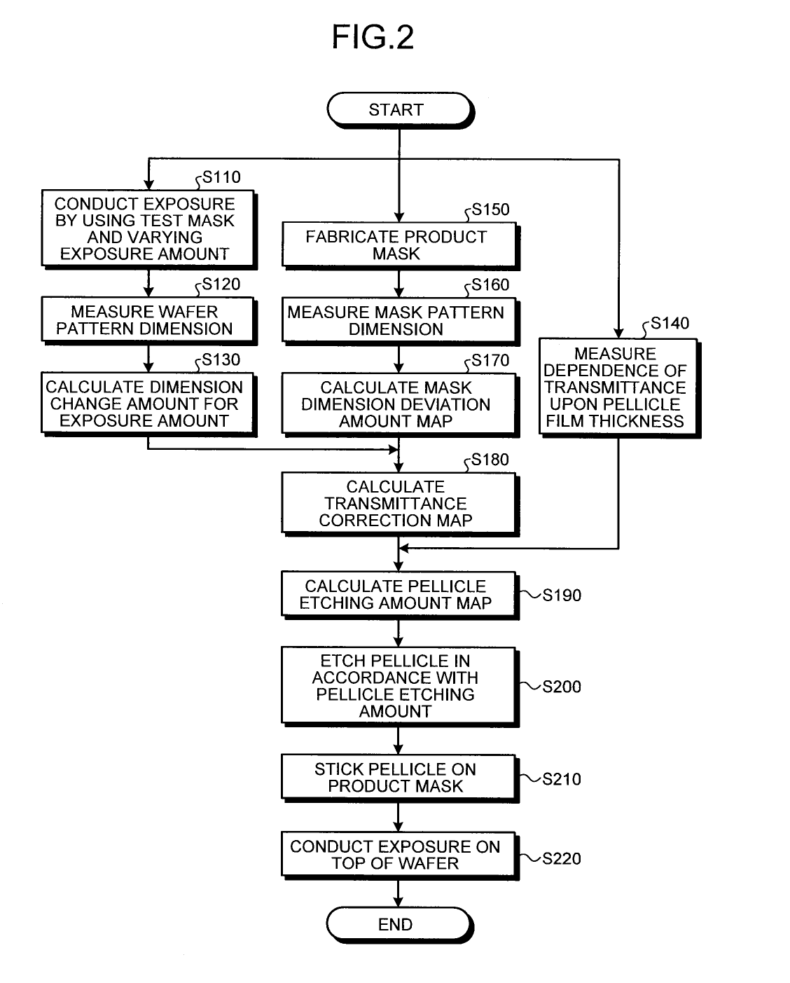

A processing procedure of an exposure method according to the first embodiment will now be described. FIG. 2 is a flow chart illustrating a processing procedure of an exposure method according to the first embodiment. An etching amount for the pellicle 3A is calculated by using a computer or the like. Before conducting exposure processing using the product mask 1, a relation between a deviation amount of a mask pattern dimension from a desired value and a film thickness set in the pellicle 3A are previously derived.

Specifically, the following four relations are previously derived.

(1) A relation between a dimension deviation amount of the mask pattern and a dimension deviation amount of the wafer pattern

(2) A relation between the wafer pattern dimension and an exposure amount

(3) A relation between the exposure amount and the transmittance in the pellicle 3A

(4) A relation between a transmittance correction amount in the pellicle 3A and an etching amount for the pellicle 3A

The relation of (1) is derived by using a test mask or the like. For example, a mask pattern dimension of the test mask is measured. In addition, a deviation amount of the mask pattern dimension from a desired value is calculated.

Furthermore, the exposure apparatus conducts exposure on a first test wafer with a resist applied thereto, by using the test mask. As a result, a wafer pattern is formed on the first test wafer. And a dimension of the wafer pattern is measured. In addition, a deviation amount of the wafer pattern dimension from a desired value is calculated.

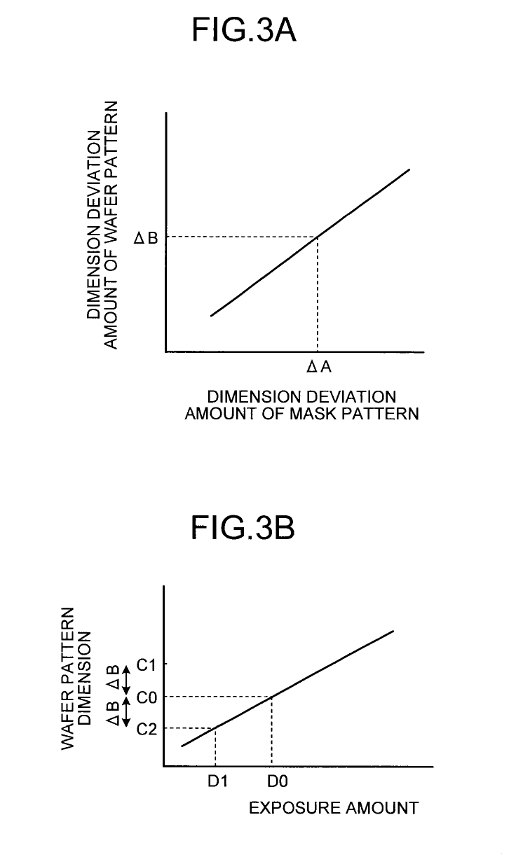

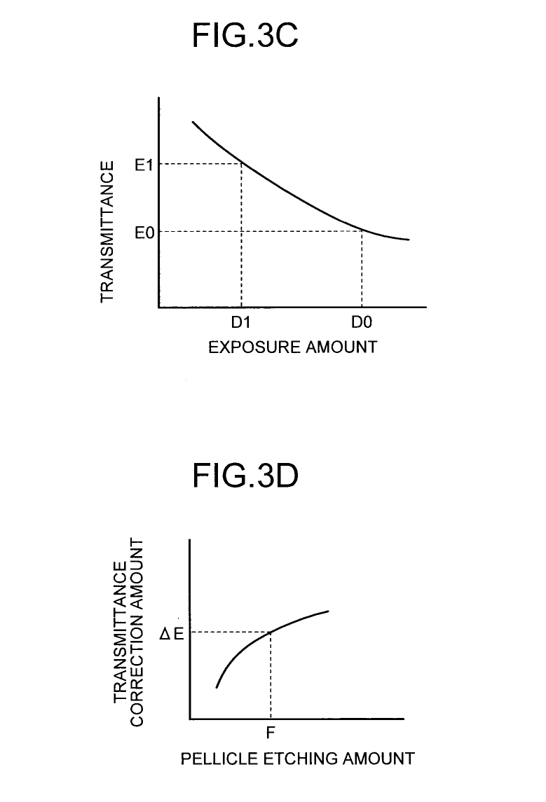

Thereafter, the relation (1), which is the relation between the dimension deviation amount of the mask pattern and the dimension deviation amount of the wafer pattern, is derived. FIG. 3A is a diagram illustrating the relation between the dimension deviation amount of the mask pattern and the dimension deviation amount of the wafer pattern. An abscissa axis in FIG. 3A represents the dimension deviation amount of the mask pattern, and an ordinate axis represents the dimension deviation amount of the wafer pattern.

Furthermore, the relation of (2) is also derived by using the test mask or the like. The exposure apparatus conducts exposure on a second test wafer with a resist applied, by using a test mask and varying the exposure amount every shot (step S110). In other words, the exposure apparatus conducts exposure on the second test wafer while changing the exposure amount every shot.

As a result, a wafer pattern (resist pattern) that differs in exposure amount every shot is formed on the second test wafer. By the way, the wafer pattern at this time may be a lower layer side pattern formed by conducting etching from the top of the resist pattern.

After the wafer pattern is formed, a wafer pattern dimension is measured (step S120). And the relation (2), which is the relation between the exposure amount and the wafer pattern dimension, is calculated. In other words, a dimension change amount of the wafer pattern for a change amount of the exposure amount is calculated (step S130). FIG. 3B is a diagram illustrating the relation between the exposure amount and the wafer pattern dimension. An abscissa axis in FIG. 3B represents the exposure amount, and an ordinate axis represents the wafer pattern dimension.

The relation of (3), which is the relation between the exposure amount and the transmittance in the pellicle 3A, may be calculated by using, for example, a computer or the like, or may be derived by measuring an actual exposure amount and an actual transmittance. FIG. 3C is a diagram illustrating the relation between the exposure amount and the transmittance. An abscissa axis in FIG. 3C represents the exposure amount, and an ordinate axis represents the transmittance in the pellicle 3A. It is possible to expose the wafer with a desired exposure amount by previously setting a transmittance according to a desired exposure amount in the pellicle 3A without the necessity for the exposure apparatus to change the exposure amount. In the present embodiment, therefore, the exposure amount with which the wafer is irradiated is adjusted by adjusting the transmittance of the pellicle 3A in the shot.

Furthermore, the relation of (4), which is the relation between the transmittance correction amount in the pellicle 3A and the etching amount for the pellicle 3A, is derived by, for example, measuring an actual transmittance and an actual film thickness of the pellicle 3A. In other words, dependence of the transmittance upon the film thickness of the pellicle is measured (step S140). Thereafter, the relation of (4) is derived by using the dependence of the transmittance upon the film thickness of the pellicle.

FIG. 3D is a diagram illustrating the relation between the pellicle etching amount and the transmittance correction amount. An abscissa axis in FIG. 3D represents the etching amount for the pellicle 3A and an ordinate axis represents the transmittance correction amount in the pellicle 3A. In the present embodiment, the pellicle 3A is etched by an amount according to a desired transmittance correction amount. By the way, the relation of (4) may be calculated by using a computer or the like.

After the relations (1) to (4) illustrated in FIG. 3A to FIG. 3D are derived, the pellicle 3A is fabricated every product mask 1. And after the product mask 1 is fabricated (step S150), the mask pattern dimension of the product mask 1 is measured (step S160). In addition, a dimension deviation amount of the mask pattern from the desired value is calculated on the basis of the mask pattern dimension of the product mask 1 and a desired value (target value) of the mask pattern dimension. The dimension deviation amount of the mask pattern is calculated as a map of dimension deviation amount in the shot (a mask dimension deviation amount map 10 which will be described later) (step S170).

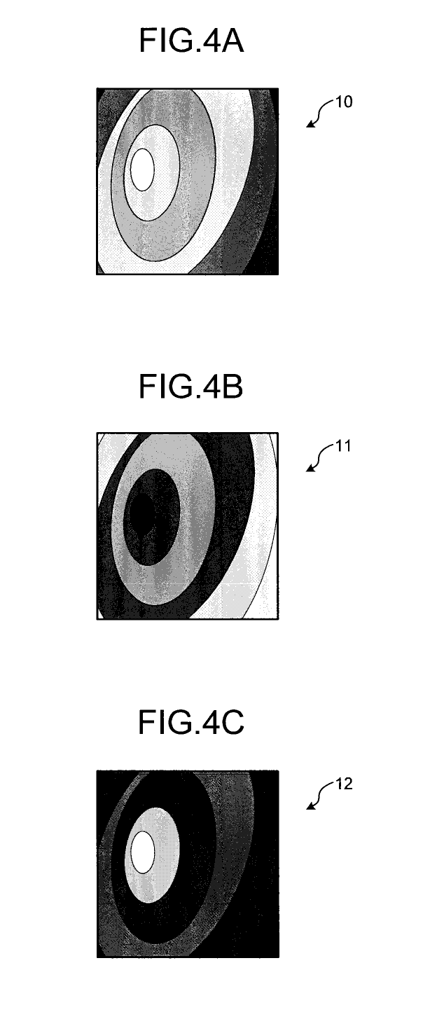

FIG. 4A is a diagram illustrating an example of a mask dimension deviation amount map. A mask dimension deviation amount map 10 is a map illustrating distribution of the dimension deviation amount of the mask pattern in the shot. The mask pattern of the product mask 1 illustrates various dimension deviation amounts in the shot. In the mask dimension deviation amount map 10 in FIG. 4A, a place where the dimension deviation amount is large is illustrated by thick shading and a place where the dimension deviation amount is small is illustrated by thin shading.

After the mask dimension deviation amount map 10 of the product mask 1 is calculated, a pattern dimension of the wafer pattern in a case where the wafer pattern is formed on the wafer by using the product mask 1 is calculated by a computer or the like. Specifically, the wafer pattern dimension is calculated by using the relation between the dimension deviation amount of the mask pattern and the dimension deviation amount of the wafer pattern illustrated in FIG. 3A.

For example, in a case where the dimension deviation amount of the mask pattern ΔA, ΔB corresponding to ΔA is calculated as the dimension deviation amount of the wafer pattern. The dimension deviation amount of the wafer pattern is calculated as a map of the dimension deviation amount in the shot (wafer dimension deviation amount map). The wafer dimension deviation amount map is a map illustrating distribution of the dimension deviation amount of the wafer pattern in the shot.

Thereafter, a map representing a correction amount of transmittance in the shot (a transmittance correction map 11 which will be described later) is calculated (step S180). The transmittance correction map 11 is a map illustrating distribution of the transmittance correction amount in the shot. The transmittance correction amount is a correction amount of transmittance required of the pellicle 3A in order to obtain a desired wafer pattern dimension. The transmittance correction map 11 is calculated by using the wafer dimension deviation amount map and the relations illustrated in FIG. 3B and FIG. 3C.

For example, an exposure amount required of the pellicle 3A in order to obtain a desired wafer pattern dimension is calculated by using the relation illustrated in FIG. 3B. Inclination of a graph illustrated in FIG. 3B represents a relation between a change amount of the exposure amount and a change amount of the wafer pattern dimension, and the inclination is a constant value.

As illustrated in FIG. 3B, an exposure amount of D0 is originally required in order to obtain a wafer pattern dimension of C0. In this case, it is supposed that exposure is conducted with the exposure amount of D0 in order to obtain the wafer pattern dimension of C0, but an actual wafer pattern dimension is C1 (C1=C0+ΔB). In this case, it is necessary to make the wafer pattern dimension smaller by ΔB. If exposure is conducted to be able to obtain a wafer pattern dimension of C0−ΔB=C2, therefore, the wafer pattern dimension of C0 can be obtained. Accordingly, D1 is calculated as an exposure amount corresponding to the wafer pattern dimension of C2. In other words, if exposure is conducted with the exposure amount of D0, the wafer pattern dimension of C1 is obtained, and if exposure is conducted with the exposure amount of D1, the wafer pattern dimension of C0 is obtained.

After the exposure amount of D1 is calculated, a transmittance corresponding to the exposure amount of D1 is calculated by using FIG. 3C. It is supposed that a transmittance corresponding to the exposure amount of D0 is E0 and a transmittance corresponding to the exposure amount of D1 is E1. Here, a desired wafer pattern dimension can be obtained by conducting exposure with an exposure amount of D1. Therefore, the desired wafer pattern dimension can be obtained by setting the transmittance of the pellicle 3A equal to E1.

After the transmittance is calculated, a transmittance correction value is calculated by calculating a difference between the calculated transmittance and a reference transmittance. And transmittance correction values are calculated in various positions in the shot, and consequently the transmittance correction map 11 is calculated.

FIG. 4B is a diagram illustrating an example of the transmittance correction map. The transmittance correction value exhibits various values in the shot. In the transmittance correction map 11 in FIG. 4B, a place where the transmittance correction amount is large is illustrated by thick shading and a place where the transmittance correction amount is small is illustrated by thin shading.

After the transmittance correction map 11 is calculated, a pellicle etching amount map 12 which will be described later is calculated by using the relation (4) illustrated in FIG. 3D (step S190). FIG. 4C is a diagram illustrating an example of the pellicle etching amount map 12. The pellicle etching amount map 12 is a map illustrating distribution of the pellicle etching amount in the shot.

The pellicle etching amount exhibits various values in the shot. In the pellicle etching amount map 12 in FIG. 4C, a place where the pellicle etching amount is large is illustrated by thick shading and a place where the pellicle etching amount is small is illustrated by thin shading.

It is supposed that in a case where a reference (before etching) transmittance of the pellicle 3A is E0, a desired wafer pattern dimension can be obtained by setting the transmittance of the pellicle 3A equal to E1. In this case, a value of F corresponding to E1−E0=ΔE is calculated as the pellicle etching amount on the basis of FIG. 3D. In other words, the desired wafer pattern dimension can be obtained if the pellicle etching amount is set equal to F.

After the pellicle etching amount map 12 is calculated, the pellicle 3A is etched in accordance with the pellicle etching amount of the pellicle etching amount map 12 (step S200). The pellicle 3A is shaven by using any of the particle beam technique, dry etching, laser aberration technique, and the like. And the pellicle 3A with a pellicle film shaven is stuck on the product mask 1 (step S210).

A large area can be worked in the lump with fine precision in the depth direction by shaving the pellicle 3A with dry etching. Furthermore, a small area can be worked in a short time by shaving the pellicle 3A with the laser aberration technique.

Thereafter, exposure processing on the wafer is conducted by using the product mask 1 with the pellicle 3A stuck thereon (step S220). In the present embodiment, the pellicle 3A is etched with various etching amounts every position in the shot to obtain a desired wafer pattern dimension. Therefore, the desired wafer pattern dimension can be obtained by conducting exposure with the pellicle 3A. Since the pellicle 3A is stuck on the product mask 1 in this way, the dimension deviation amount of the product mask 1 is canceled by the transmittance adjustment of the pellicle 3A. As a result, it becomes possible to bring the dimension in the shot on the wafer face (wafer pattern dimension) close to a desired dimension.

By the way, in the present embodiment, the relations in FIG. 3A to FIG. 3D and the like are calculated by using the test mask. However, the relations in FIG. 3A to FIG. 3D and the like may be calculated by using any mask. Furthermore, in the present embodiment, the pellicle 3A is fabricated for the product mask. However, the pellicle 3A may be fabricated for any mask.

Furthermore, as for the processing in the steps S110 to S130 and the processing in the steps S150 to S170, either of them may be conducted earlier. Furthermore, as for the processing in the steps S110 to S130 and the steps S150 to S180 and the processing in the step S140, either of them may be conducted earlier.

Furthermore, the pellicle etching amount may be calculated by using a relation between the exposure amount and the dimension deviation amount of the wafer pattern instead of the relation illustrated in FIG. 3B (the relation between the exposure amount and the transmittance). Furthermore, the pellicle etching amount may be calculated by using a relation between a correction amount of the exposure amount and the wafer pattern dimension instead of the relation illustrated in FIG. 3B. Furthermore, the pellicle etching amount may be calculated by using a relation between the correction amount of the exposure amount and the dimension deviation amount of the wafer pattern instead of the relation illustrated in FIG. 3B.

Furthermore, the pellicle etching amount may be calculated by using a relation between the exposure amount and the transmittance correction amount instead of the relation illustrated in FIG. 3C (the relation between the exposure amount and the transmittance). Furthermore, the pellicle etching amount may be calculated by using a relation between the correction amount of the exposure amount and the transmittance instead of the relation illustrated in FIG. 3C. Furthermore, the pellicle etching amount may be calculated by using a relation between the correction amount of the exposure amount and the correction amount of the transmittance instead of the relation illustrated in FIG. 3C.

Furthermore, the pellicle etching amount may be calculated by using a relation between the transmittance and a pellicle etching amount required for the transmittance instead of the relation illustrated in FIG. 3D (the relation between the transmittance correction amount and the pellicle etching amount). Furthermore, the pellicle etching amount may be calculated by using a relation between a transmittance correction amount and a pellicle film thickness corresponding to the transmittance correction amount instead of the relation illustrated in FIG. 3D.

Furthermore, it is also possible to previously combine any of relations illustrated in FIG. 3A to FIG. 3D and calculate the pellicle etching amount by using a relation obtained by the combination. For example, a relation between the dimension deviation amount of the mask pattern and the pellicle etching amount is derived by combining relations illustrated in FIG. 3A to FIG. 3D. It becomes possible to calculate the pellicle etching amount from the dimension deviation amount of the mask pattern by using this relation.

Furthermore, for example, the pellicle etching amount may be calculated by using a relation between the dimension deviation amount of the mask pattern and the exposure amount instead of the relations illustrated in FIG. 3A and FIG. 3B. In this case, an exposure amount is calculated by using the relation between the dimension deviation amount of the mask pattern and the exposure amount, and the pellicle etching amount is calculated on the basis of the exposure amount.

In the same way, the relation illustrated in FIG. 3B and the relation illustrated in FIG. 3C may be combined with each other previously. Furthermore, the relation illustrated in FIG. 3C and the relation illustrated in FIG. 3D may be combined with each other previously. Furthermore, the relations illustrated in FIG. 3A to FIG. 3C may be combined, or the relations illustrated in FIG. 3B to FIG. 3D may be combined.

Furthermore, the film thickness of the pellicle 3A may be adjusted locally, or the whole of the pellicle 3A may be adjusted. Furthermore, the film thickness of the pellicle 3A may be adjusted on the basis of reflectance distribution of the product mask 1. As a result, it becomes possible to conduct correction of the reflectance distribution of the product mask 1 by using the pellicle 3A, and a pattern dimension on a wafer face becomes a desired dimension.

Furthermore, the film thickness of the pellicle 3A may be adjusted in a state in which the pellicle 3A is stuck on the product mask 1, or may be adjusted in a state in which the pellicle 3A is detached from the product mask 1. In a case where the film thickness of the pellicle 3A is adjusted in the state in which the pellicle 3A is detached from the product mask 1, it becomes possible to adjust the film thickness of the pellicle 3A easily.

According to the first embodiment, the transmittance of the pellicle 3A is adjusted according to the dimension deviation amount of the mask pattern in this way. This brings about a change in an amount of light with which the product mask 1 is irradiated, or an amount of light which is reflected by the product mask 1 and with which the wafer is irradiated. Accordingly, a dimension of a pattern transferred to the wafer can be accurately controlled on the wafer. In the exposure apparatus of reflection type as well, therefore, it becomes possible to correct the wafer pattern dimension with high precision.

### Second Embodiment

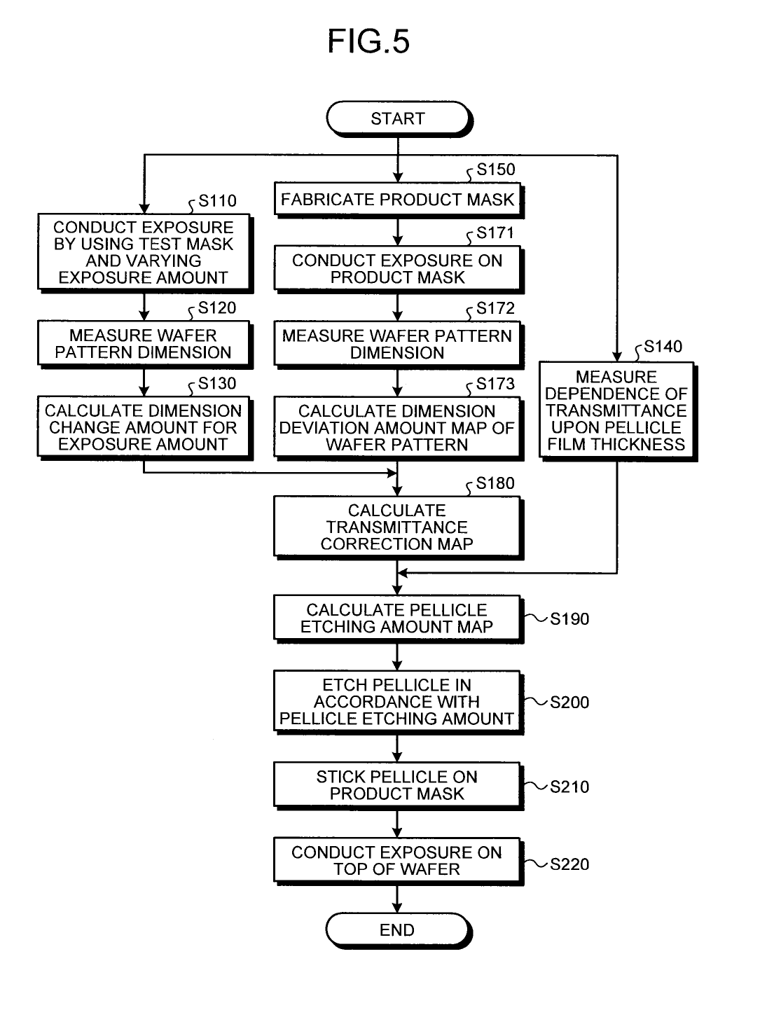

A second embodiment will now be described with reference to FIG. 5. In the second embodiment, a wafer pattern is actually formed by using the product mask and a dimension deviation amount map of the wafer pattern is calculated by measuring a wafer pattern dimension.

FIG. 5 is a flow chart illustrating a processing procedure of an exposure method according to the second embodiment. In FIG. 5, as for the same processing as processing described with reference to FIG. 2, duplicated description will be omitted. In the present embodiment, calculation processing of the relation illustrated in FIG. 3A is omitted. Furthermore, instead of processing in the step S160 and the step S170, processing in steps S171 to S173 is executed.

The relations illustrated in FIG. 3B and FIG. 3C are calculated by using the test mask (steps S110 to S140). And after the product mask 1 is fabricated (step S150), the exposure apparatus conducts exposure on a third test wafer by using the product mask 1 (step S171). As a result, a wafer pattern is formed on the third test wafer. And a wafer pattern dimension in a shot is measured (step S172).

In addition, a dimension deviation amount of the wafer pattern from a desired value is calculated on the basis of the wafer pattern dimension and a desired value (target value) of the wafer pattern dimension. The dimension deviation amount of the wafer pattern is calculated as a map of the dimension deviation amount in the shot (referred to as wafer dimension deviation map) (step S173).

Thereafter, a transmittance correction map 11 and a pellicle etching amount map 12 are calculated by processing similar to that in the first embodiment (steps S180 and S190). And the pellicle 3A is etched (step S200) and the pellicle 3A is stuck on the product mask 1 (step S210) by processing similar to that in the first embodiment. Thereafter, exposure processing on the wafer is conducted by using the product mask 1 with the pellicle 3A stuck thereon (step S220).

By the way, either of the processing in the steps S110 to S120 and the processing in the steps S150 and S171 to S173 may be conducted earlier. Furthermore, either of the processing in the steps S110 to S130, S150, and S171 to S180 and the processing in the step S140 may be conducted earlier.

According to the second embodiment, the transmittance of the pellicle 3A is adjusted on the basis of the dimension deviation amount of the wafer pattern formed on the wafer, in this way. In the exposure apparatus of reflection type as well, therefore, it becomes possible to correct the wafer pattern dimension with further higher precision.

### Third Embodiment

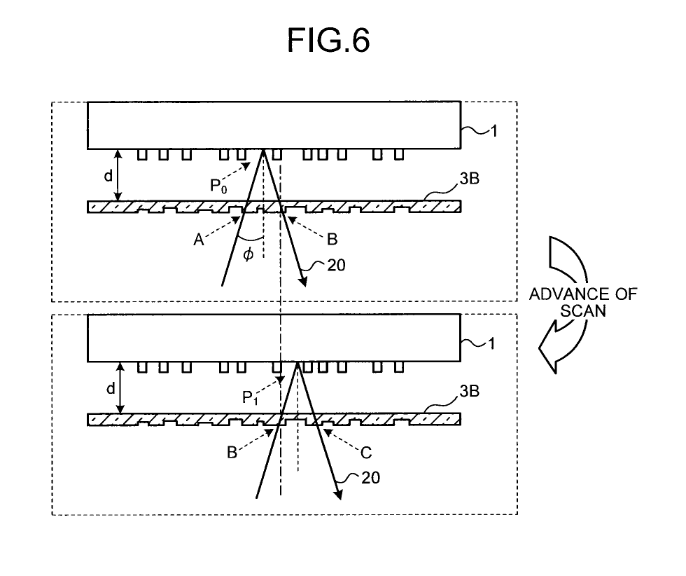

A third embodiment will now be described with reference to FIG. 6. In the third embodiment, the transmittance correction map is calculated in consideration of an irradiation angle of exposure light with respect to the product mask 1. By the way, in the present embodiment, a case where the pellicle is a pellicle 3B will now be described.

FIG. 6 is a diagram for explaining a relation between an irradiation angle of exposure light and a position where the exposure light passes through the pellicle. Since the exposure apparatus of reflection type has a mask of reflection type, exposure light 20 (incident light) incident on the product mask 1 and the pellicle 3B has an angle of inclination of φ=approximately 4 to 10 degrees.

In a case where a position on the product mask 1 indicated by position P₀ is irradiated with the exposure light 20, therefore, a point A where the exposure light 20 passes through (is incident on) the pellicle 3B and a point B where the exposure light 20 reflected by a mask face passes through (exits) the pellicle 3B are not in the same position.

When exposure is conducted in the position P₀, the exposure light 20 is incident from the point A on the pellicle 3B and exits from the point B on the pellicle 3B. Furthermore, when exposure is conducted in a position P₁, the exposure light 20 is incident from the point B on the pellicle 3B and exits from a point C on the pellicle 3B.

As exposure processing (scan movement) advances in this case, the point B where outgoing light from the point P₀ passes through and the point B where incident light to the point P₁ which is the next exposure position passes through overlap each other. In other words, there are positions P₀ and P₁ that cause the position (the point B) of light incident on the pellicle 3B at the time when the position P₁ is exposed and the position (the point B) of outgoing light from the pellicle 3B at the time when the position P₀ is exposed to overlap each other.

In this case, a transmittance Tₚ₀ required in the position P₀ becomes a value obtained by multiplying a transmittance T_{A} at the point A by a transmittance T_{B} at the point B. In the same way, a transmittance Tₚ₁ required in the position P₁ becomes a value obtained by multiplying a transmittance T_{B} at the point B by a transmittance T_{C} at the point C.

Representing them by a numeral formula, T_{P}(x)=T(x−d·tan φ)×T(x+d·tan φ) is obtained. Here, d is a distance between a back of the pellicle 3B and a surface of the product mask 1. Furthermore, T(x−d·tan φ)×T(x+d·tan φ) is T_{A}×T_{B} or T_{B}×T_{c}. In the present embodiment, the transmittance correction map 11 that satisfies this numeral formula is generated. For example, at the point B on the pellicle 3B, a transmittance that satisfies the transmittance T_{P0} required for the position P₀ and satisfies the transmittance T_{P1} required for the position P₁ is set.

By the way, in the present embodiment, the transmittance setting processing in one-dimensional direction has been described in order to facilitate the description. In the actual calculation, however, the transmittance may be calculated in two dimensions (a main face direction of the pellicle 3B).

According to the third embodiment, the transmittance of the pellicle 3B is set in consideration of the irradiation angle of the exposure light 20 in this way. As a result, it becomes possible to set an accurate transmittance. Therefore, a wafer pattern dimension having further high precision can be obtained.

### Fourth Embodiment

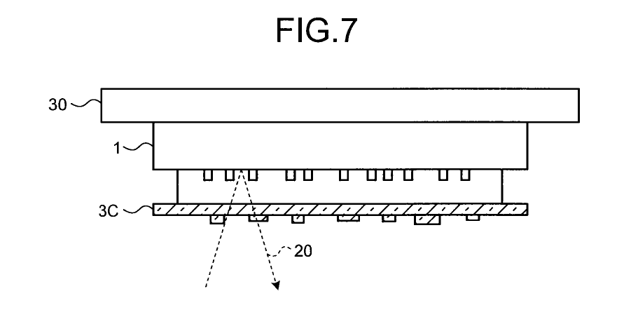

A fourth embodiment will now be described with reference to FIG. 7. In the fourth embodiment, a film is deposited on the pellicle according to a dimension deviation amount of the wafer pattern dimension. The transmittance of the pellicle in the shot is adjusted by this. By the way, a case where the pellicle is a pellicle 3C will be described in the present embodiment.

FIG. 7 is a diagram, illustrating a sectional configuration of a mask according to the fourth embodiment. By the way, components achieving the same function as the product mask 1 in the first embodiment illustrated in FIG. 7 are denoted by like reference characters, and duplicated description will be omitted. In the present embodiment, the product mask 1 has a pellicle 3C. The pellicle 3C is stuck on a surface side of the product mask 1 in a position located at a predetermined distance from the mask pattern.

The pellicle 3C is adjusted in transmittance by adjusting a deposition amount of a film. In the present embodiment, a relation between a transmittance correction amount in the pellicle 3C and a deposition amount of a film on the pellicle 3C is derived instead of the relation of (4) described in the first embodiment.

The deposition amount of the film on the pellicle 3C is calculated by a processing procedure similar to that in the first or second embodiment. On the pellicle 3C, deposition of a local film using, for example, FIB (Focused Ion Beam) or an electron beam, or deposition of a film on a large area using, for example, partial drop of a liquid drop using an ink jet technique, sputtering, or CVD (Chemical Vapor Deposition), or the like is conducted. In this case, a film of a deposited film is made thick previously for a place on the pellicle 3C where the transmittance is to be made small. After the film is deposited on the pellicle 3C, the pellicle 3C is stuck on the product mask 1. By the way, the film deposited on the pellicle 3C may be any film. For example, a pellicle material similar to that of the pellicle 3C may be deposited on the pellicle 3C.

As a result, the pellicle 3C itself is not consumed even in a case where the adjustment of the transmittance is repeated for the pellicle 3C. As a result, it is possible to extend the life of the pellicle 3C. By the way, the transmittance of the pellicle 3C may be adjusted by oxidizing or deoxidizing the pellicle material with respect to the pellicle 3C. Furthermore, the film may be deposited on the pellicle 3C by an amount according to a dimension deviation amount of the mask pattern dimension.

The pellicles 3A to 3C are fabricated, for example, every layer of the wafer process (every product mask). And a semiconductor device (semiconductor integrated circuit) is manufactured by using any of the pellicles 3A to 3C adjusted in transmittance as occasion demands. Specifically, any of the pellicles 3A to 3C adjusted in transmittance is stuck on the product mask 1.

And exposure is conducted by using the product mask 1 for a wafer with a resist applied, and thereafter the wafer is developed and a resist pattern is formed on the wafer. And a lower layer side of the resist pattern is etched by using the resist pattern as a mask. As a result, a wafer pattern corresponding to the resist pattern is formed on the wafer. When manufacturing a semiconductor device, the above-described pellicle etching amount map calculation processing, fabrication processing of the pellicles 3A to 3C, fabrication processing of the product mask 1, exposure processing, development processing, etching processing, and the like are repeated every layer.

According to the fourth embodiment, a film is deposited on the pellicle according to the dimension deviation amount of the wafer pattern dimension in this way. As a result, it becomes possible to repeat the transmittance adjustment on the pellicle 3C a large number of times.

According to first to fourth embodiments, it becomes possible to correct a wafer pattern formed on a wafer, with high precision in an exposure apparatus of reflection type as well in this way.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An exposure method comprising:
adjusting a transmittance of a pellicle every position of a mask pattern included in a reflection type mask; and
conducting exposure onto a substrate by using the reflection type mask with the pellicle stuck thereon.

2. The exposure method according to claim 1, further comprising:
calculating a mask pattern dimension deviation amount, which is a deviation amount of a dimension from an ideal value on the mask pattern of the reflection type mask;
calculating a transmittance correction amount of the pellicle according to the mask pattern dimension deviation amount; and
adjusting the transmittance of the pellicle on the basis of the calculated transmittance correction amount, when adjusting the transmittance.

3. The exposure method according to claim 1, further comprising:
calculating a pattern dimension deviation amount on a substrate, which is a deviation amount of a dimension from an ideal value, in a pattern on the substrate formed in a case where exposure is conducted onto the substrate by using the reflection type mask;
calculating a transmittance correction amount of the pellicle according to the pattern dimension deviation amount on the substrate; and
adjusting the transmittance of the pellicle on the basis of the calculated transmittance correction amount, when adjusting the transmittance.

4. The exposure method according to claim 1, wherein the transmittance of the pellicle is adjusted by adjusting a pellicle film thickness, which is a film thickness of the pellicle.

5. The exposure method according to claim 4, wherein the pellicle film thickness is adjusted by shaving the pellicle.

6. The exposure method according to claim 5, wherein the pellicle film is shaven by using dry etching.

7. The exposure method according to claim 5, wherein the pellicle film is shaven by using laser aberration.

8. The exposure method according to claim 1, wherein the transmittance of the pellicle is adjusted by depositing a film on the pellicle.

9. The exposure method according to claim 1, wherein the transmittance of the pellicle is adjusted by oxidizing or deoxidizing a pellicle material of the pellicle.

10. The exposure method according to claim 1, wherein the transmittance of the pellicle is adjusted in a state in which the pellicle is detached from the reflection type mask.

11. A reflection type mask comprising:
a mask pattern; and
a pellicle adjusted in transmittance every position of the mask pattern.

12. The reflection type mask according to claim 11, wherein the transmittance of the pellicle is adjusted on the basis of a transmittance correction amount of the pellicle, which is calculated according to a deviation amount of a dimension from an ideal value in the mask pattern.

13. The reflection type mask according to claim 11, wherein the transmittance of the pellicle is adjusted on the basis of a transmission correction amount of the pellicle, which is calculated according to a deviation amount of a dimension from an ideal value, in a pattern on the substrate formed in a case where exposure is conducted onto the substrate by using the reflection type mask.

14. The reflection type mask according to claim 12, wherein the transmittance of the pellicle is adjusted by adjusting a pellicle film thickness, which is a film thickness of the pellicle.

15. The reflection type mask according to claim 14, wherein the pellicle film thickness is adjusted by shaving the pellicle.

16. The reflection type mask according to claim 15, wherein the transmittance of the pellicle is adjusted by depositing a film on the pellicle.

17. The reflection type mask according to claim 11, wherein the transmittance of the pellicle is adjusted by oxidizing or deoxidizing a pellicle material of the pellicle.

18. A semiconductor device manufacturing method comprising:
adjusting a transmittance of a pellicle every position of a mask pattern included in a reflection type mask;
conducting exposure onto a substrate by using the reflection type mask with the pellicle stuck thereon; and
forming a resist pattern on the substrate by developing the substrate.

19. The semiconductor device manufacturing method according to claim 18, further comprising:
calculating a mask pattern dimension deviation amount, which is a deviation amount of a dimension from an ideal value on a mask pattern of the reflection type mask;
calculating a transmittance correction amount of the pellicle according to the mask pattern dimension deviation amount; and
adjusting the transmittance of the pellicle on the basis of the calculated transmittance correction amount, when adjusting the transmittance.

20. The semiconductor device manufacturing method according to claim 18, further comprising:
calculating a pattern dimension deviation amount on a substrate, which is a deviation amount of a dimension from an ideal value, in a pattern on the substrate formed in a case where exposure is conducted onto the substrate by using the reflection type mask;
calculating a transmittance correction amount of the pellicle according to the pattern dimension deviation amount on the substrate; and
adjusting the transmittance of the pellicle on the basis of the calculated transmittance correction amount, when adjusting the transmittance.
